(19) United States
(12) Patent Application Publication
(10) Pub. No.: US 2006/0043593 A1
(43) Pub. Date: Mar. 2, 2006

(54) Connecting apparatus, semiconductor chip inspecting apparatus, and method for manufacturing semiconductor device

(76) Inventors: Terutaka Mori, Urayasu (JP); Yasunori Narizuka, Hiratsuka (JP); Akira Yabushita, Yokohama (JP); Etsuko Takane, Yokohama (JP); Akio Hasebe, Kodaira (JP); Kenji Kawakami, Kai (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/184,980

(22) Filed: Jul. 20, 2005

(30) Foreign Application Priority Data
Sep. 2, 2004 (JP) 2004-255852

(51) Int. Cl. H01L 23/52

(52) U.S. Cl. 257/758

(57) ABSTRACT

In the connecting apparatus for inspecting the semiconductor chip, in which contact terminals are electrically connected to each of the plurality of electrode pads formed on the semiconductor chips, a part of metal projections in the shape of quadrangular pyramid which constitute the contact terminals is composed of insulator in the present invention. Therefore, the inspection of semiconductor chips performed by simultaneously transmitting high-speed signals to the plurality of minute electrode pads arranged at a narrow pitch on the semiconductor chips can be realized.

### CROSS-REFERENCE TO RELATED APPLICATION

The present application claims priority from Japanese Application JP2004-255852 filed on Sep. 2, 2004, the content of which is hereby incorporated by reference into this application.

### TECHNICAL FIELD OF THE INVENTION

The present invention relates to connecting apparatus used to inspect a semiconductor chip, semiconductor chip inspecting apparatus using the connecting apparatus, and a method of manufacturing a semiconductor device using them. More particularly, the present invention relates to a technology effectively applied to a connecting technology for a semiconductor chip which transmits high-speed signals and in which minute electrodes are arranged at a narrow pitch or a plurality of electrode pads can be connected at the same time.

### BACKGROUND OF THE INVENTION

According to the examination by the inventors of the present invention, the following technologies are known as the semiconductor chip inspecting technology.

For example, in the field of the semiconductor module in recent years, the so-called multi-chip module in which semiconductor chips such as LSI and memory are integrated has become more and more popular. This is largely because of the significant improvement in the integration degree of the semiconductor chips resulting from the development of the bare chip technology.

FIG. 14A is a perspective view showing a wafer 1 on which a large number of semiconductor chips 2 are arranged, and FIG. 14B is an enlarged perspective view showing one semiconductor chip 2. A large number of semiconductor chips 2 are arranged and formed on the wafer 1 and are separated from each other for use. A large number of electrode pads 3 are arrayed on the surface of the semiconductor chip 2 along the periphery thereof. With the increase of the integration degree of the semiconductor chip 2, the pitch of the electrode pads 3 becomes narrower and the density of the electrode pads 3 is further increased. The pitch of the electrode pads 3 becomes narrower, and the product with the pitch of 20 μm has been developed. With respect to the increase in the density of the electrode pads 3, the number of lines of the arranged electrode pads 3 tends to increase from one line to two lines, and further, the electrode pads 3 are arranged on the whole surface in some cases.

Also, the operation speed of the semiconductor chip is significantly increased, and the clock reaches several GHz in the microcomputer.

In order to manufacture the semiconductor chips and the multi chip module in which the semiconductor chips are mounted in good yield, the technology for efficiently inspecting the electrical properties in the late stage of the process for manufacturing the semiconductor chip is required.

In the conventional technology, the connecting apparatus comprising a wiring board for inspection and tungsten probes obliquely protruded from the wiring board for inspection has been used in general. Furthermore, as the technology for obtaining the minute contact terminals, Japanese Patent Laid-Open Publication No. 7-283280 is proposed.

### SUMMARY OF THE INVENTION

Incidentally, as a result of the examination for the above-described technology for inspecting the semiconductor chip by the inventors of the present invention, the following facts have been revealed.

For example, due to the miniaturization of the chip and the increase in the diameter of the wafer, the number of semiconductor chips obtained from one wafer has been increased, and the amount of time required to inspect these chips has also been drastically increased. In order to manufacture the connecting apparatus used for the minute electrode pads arranged at a narrow pitch, it is necessary to appropriately combine the minute contact terminals at a narrow pitch equivalent to that of the electrode pads, the wiring board for inspection having the narrow-pitch wiring, and the narrow-pitch connecting technology for connecting them. Also, although it is possible to reduce the inspection time by connecting a plurality of semiconductor chips at the same time, it is necessary to precisely fix the shape and the position of the contact terminals for its achievement.

Also, in the connecting apparatus using tungsten probes, the tungsten probe is brought into contact with the electrode pad of the semiconductor chip to be inspected, and then, the contact pressure is applied to perform the scrub operation. By doing so, the oxide film naturally formed on the electrode pad due to the oxygen in the air is removed to electrically connect the probe and the electrode pad. Then, the electrical properties of the semiconductor chip are inspected.

However, as described above, although the density of the electrode pads of the semiconductor chip is increased and the pitch of the electrode pads becomes drastically narrower due to the increase of the wiring density, it becomes almost impossible to make the tungsten probe thinner. Also, when the probe is made thinner, the lifetime thereof is reduced and the frequent maintenance is required. As a result, the cost therefor is inevitably increased. Also, the occurrence of the indentations and the electrode waste due to the scrub operation makes the reinspection difficult and may cause the product defects. In addition, since the tungsten probe and the wiring board for inspection are produced separately and they are connected at a narrow pitch, the problems concerning the alignment accuracy and the microscopic connection have become more and more obvious. Therefore, it is difficult to perform the inspection of the minute electrode pads densely arranged at a narrow pitch with the connecting apparatus using the tungsten probe.

Also, in the description of Japanese Patent Laid-Open Publication No. 7-283280, the hole used as the mold for forming the contact terminal is formed by the anisotropic etching of (100) surface of the silicon wafer, and metal is filled in this mold to form the contact terminal. Next, an insulating film composed of a polyimide film and lead-out wiring are formed separately. Furthermore, a silicon wafer functioning as a buffer layer and a substrate is sandwiched and bonded between the insulating film and the wiring board and then the mold is removed. Thereafter, the lead-out wiring is connected to the electrode pad of the wiring board with solder. The shape of the contact terminal is a quadrangular pyramid which reflects the shape of the hole formed in the silicon wafer. The size of the hole depends on the size of the opening formed in the silicon dioxide by the photolithography and the etching conditions. The pitch of the holes is determined by the pitch of the openings of the silicon dioxide. Also, the tip portion of the contact terminal is worn out at each contact with the object to be inspected. As a result, when the pitch of the holes is reduced, the height of the contact terminal is reduced and the lifetime thereof is also reduced. Furthermore, if the height of the foreign matter adhered onto the object to be inspected is larger than that of the contact terminal, the contact terminal is not appropriately brought into contact with the object to be inspected and the contact terminal itself is damaged. Therefore, it is necessary to make the size of the contact terminal as large as possible.

In consideration of the problems described above, an object of the present invention is to provide a wiring board for inspection on which minute and uniform-shaped contact terminals whose size is almost equivalent to that of the electrode pads are densely arranged at a narrow pitch equal to that of the electrode pads and the contact terminals with the height larger than that of the contact terminal defined by the electrode pad pitch are arranged, to provide connecting apparatus for appropriately making the electrical connection therebetween in which a large number of electrode pads or electrode pads of a plurality of chips can be connected at the same time, and to provide a semiconductor chip inspection technology without losing the advantages described above.

The above and other objects and novel characteristics of the present invention will be apparent from the description and the accompanying drawings of this specification.

The typical ones of the inventions disclosed in this application will be briefly described as follows.

For the achievement of the object described above, the first connecting apparatus according to the present invention comprises: contact terminals electrically contacting with the object to be inspected; an insulating layer having the contact terminals provided on one surface thereof; and a wiring layer formed on the other surface of the insulating layer and electrically connected to the contact terminals through via interconnect lines, wherein the contact terminals have metal projections in the shape of quadrangular pyramid and a part of the quadrangular pyramid of the metal projection is composed of an insulator.

Also, the second connecting apparatus according to the present invention comprises: contact terminals contacting with the object to be inspected; a first insulating layer having the contact terminals provided on one surface thereof; a first wiring layer formed on the other surface of the first insulating layer and electrically connected to the contact terminals through via interconnect lines; a second insulating layer having the first wiring layer provided on one surface thereof; and a second wiring layer formed on the other surface of the second insulating layer and electrically connected to the first wiring layer through via interconnect lines, wherein the contact terminals have metal projections in the shape of quadrangular pyramid and a part of the quadrangular pyramid of the metal projection is composed of an insulator.

Further, in the first and second connecting apparatuses according to the present invention, the part of the quadrangular pyramid of the metal projection is a part (e.g. a peripheral part) of the bottom portion of the metal projection. Also, each of the contact terminals has a plurality of tip portions for one wiring.

Also, in the first and second connecting apparatuses according to the present invention, the connecting apparatus has a holding member for fixing a peripheral portion of the insulating layer on which the contact terminals are provided, a pressing piece for projecting the contact terminals from the holding member, and a center pivot for pushing the pressing piece. In addition, the pressing piece has a protruding portion with a flat surface, a buffer layer in contact with the protruding portion is provided, and a region in which the contact terminals are arranged is projected along the flat surface of the protruding portion with sandwiching the buffer layer therebetween. Furthermore, the pressing piece has screws which are screwed up at the left, right, back and forth around the center pivot to be adjustable, and a projecting amount of the region in which the contact terminals are arranged is defined in accordance with a protrusion of the screws from a surface of the protruding portion of the pressing piece.

Also, in the first and second connecting apparatuses according to the present invention, the contact terminal is made of at least one metal or alloy of metals selected from a group including nickel, rhodium, palladium, iridium, ruthenium, tungsten, chromium, copper and tin.

Also, the semiconductor chip inspecting apparatus according to the present invention uses the connecting apparatus described above. Further, the semiconductor chip inspecting apparatus comprises: a sample support system for supporting a wafer to be inspected; an inspection connecting system including the connecting apparatus which contacts with electrode pads of semiconductor chips on the wafer to transmit electrical signals; a drive control system for controlling an operation of the sample support system; a temperature control system for controlling a temperature of the wafer; and a tester for inspecting electrical properties of the semiconductor chip.

Also, the method of manufacturing a semiconductor device according to the present invention comprises the steps of: fabricating circuits on a wafer to form a plurality of semiconductor elements; sealing the wafer with resin; collectively inspecting electrical properties of the plurality of semiconductor elements formed on the sealed wafer; and cutting the wafer to separate each of the semiconductor elements, wherein the inspecting step uses the semiconductor inspecting apparatus described above. Furthermore, the inspecting step includes a step of evaluating electrical properties at high temperature.

More specifically, in the present invention, the connecting apparatus for contacting with the electrode pads, which are densely arranged at a narrow pitch because of the increase of the integration degree of the semiconductor chip, to inspect the semiconductor chip is manufactured by electrically connecting, via metal junction, minute contact terminals with sharp tips densely arranged at a narrow pitch equal to that of the electrode pads to wirings of a wiring board for inspection in which via interconnect lines are densely arranged without any multilayer interconnection. Also, a plurality of contact terminals are arranged for one electrode pad.

The effect obtained by the representative one of the inventions disclosed in this application will be briefly described as follows.

(1) Since a group of contact terminals are simply pressed at a low contact pressure to electrode pads such as aluminum or solder of objects to be inspected on which an oxide is formed, the stable connection with low resistance can be realized without damages due to the indentation and the electrode wastes.

(2) Since a large number of contact terminals can be easily arranged on the wiring board for inspection, the electrode pads of one or plural semiconductor chips of a large number of semiconductor chips arranged on a wafer can be surely connected at the same time, and the electrical properties of each semiconductor chip can be evaluated.

(3) It is possible to transmit the high-frequency electric signals.

(4) The electrical property evaluation at high temperature such as the burn-in test can be performed, and it is possible to evaluate the electrical properties of the semiconductor chip in which the pitch becomes narrower and the density of the electrode pads is increased.

### BRIEF DESCRIPTIONS OF THE DRAWINGS

FIG. 1 is an explanatory diagram showing a taper angle of a via according to an embodiment of the present invention;

FIG. 2A is an explanatory diagram showing the sputter defect for the via with the taper angle larger than 90 degrees according to an embodiment of the present invention;

FIG. 2B is an explanatory diagram showing the plating defect for the via with the taper angle larger than 90 degrees according to an embodiment of the present invention;

FIG. 3A to FIG. 3D are explanatory diagrams showing the manufacturing process of the connecting apparatus according to the first embodiment of the present invention;

FIG. 4A and FIG. 4B are explanatory diagrams showing the step of forming contact terminals of the connecting apparatus according to the first embodiment of the present invention, and FIG. 4A is a top plan view showing the principal part and FIG. 4B is a cross-sectional view showing the principal part taken along the line A-A′ of FIG. 4A, respectively;

FIG. 5A to FIG. 5F are explanatory diagrams showing the manufacturing process of the connecting apparatus according to the second embodiment of the present invention;

FIG. 6A to FIG. 6D are explanatory diagrams showing the manufacturing process of the connecting apparatus according to the third embodiment of the present invention;

FIG. 7A and FIG. 7B are explanatory diagrams showing the step of forming contact terminals of the connecting apparatus according to the first embodiment of the present invention, and FIG. 7A is a top plan view showing the principal part and FIG. 7B is a cross-sectional view showing the principal part taken along the line A-A′ of FIG. 7A, respectively;

FIG. 8A and FIG. 8B are explanatory diagrams showing an embodiment of the wiring board for inspection to which the contact terminals of the connecting apparatus according to the present invention are connected, and FIG. 8A is a plan view and FIG. 8B is a perspective view showing the state of the bent wiring board for inspection;

FIG. 9A and FIG. 9B are explanatory diagrams showing another embodiment of the wiring board for inspection to which the connecting terminals of the connecting apparatus according to the present invention are connected, and FIG. 9A is a plan view and FIG. 9B is a perspective view showing the state of the bent wiring board for inspection;

FIG. 10 is an explanatory diagram showing the principal part of the case where the connecting apparatus according to the present invention is mounted in the inspection connecting system;

FIG. 11 is an explanatory diagram showing the overall structure of the semiconductor chip inspecting apparatus including the connecting apparatus according to the present invention;

FIG. 12 is an explanatory diagram showing the appearance of the inspection for the semiconductor chip on which the electrode pads are arranged, in which the semiconductor chip inspecting apparatus including the connecting apparatus according to the present invention is used;

FIG. 13 is an explanatory diagram showing the method of manufacturing the semiconductor device, in which the semiconductor chip inspecting apparatus including the connecting apparatus according to the present invention is used; and

FIG. 14A is a perspective view showing a wafer to be inspected on which semiconductor chips are arranged and FIG. 14B is a perspective view showing one semiconductor chip in a general embodiment.

### DESCRIPTIONS OF THE PREFERRED EMBODIMENTS

<Embodiment for Carrying out the Present Invention>

According to an embodiment for carrying out the present invention, (1) the connecting apparatus comprising contact terminals having metal projections and a wiring layer electrically connected to the contact terminals via an insulating layer, in which a part of quadrangular pyramid of the contact terminal is composed of an insulator and (2) the semiconductor chip inspecting apparatus using the connecting apparatus and the manufacturing method using them are provided.

As an example of the step of forming a via according to the present invention, the method of forming a via by laser or dry etching using reaction gas with using a metal film adhered to an insulating layer as a mask and the method of irradiating laser positioned by optical components are shown.

In the former method described above, a mask of a metal film is formed by the photolithography. Therefore, it is possible to form the mask with a high positional accuracy.

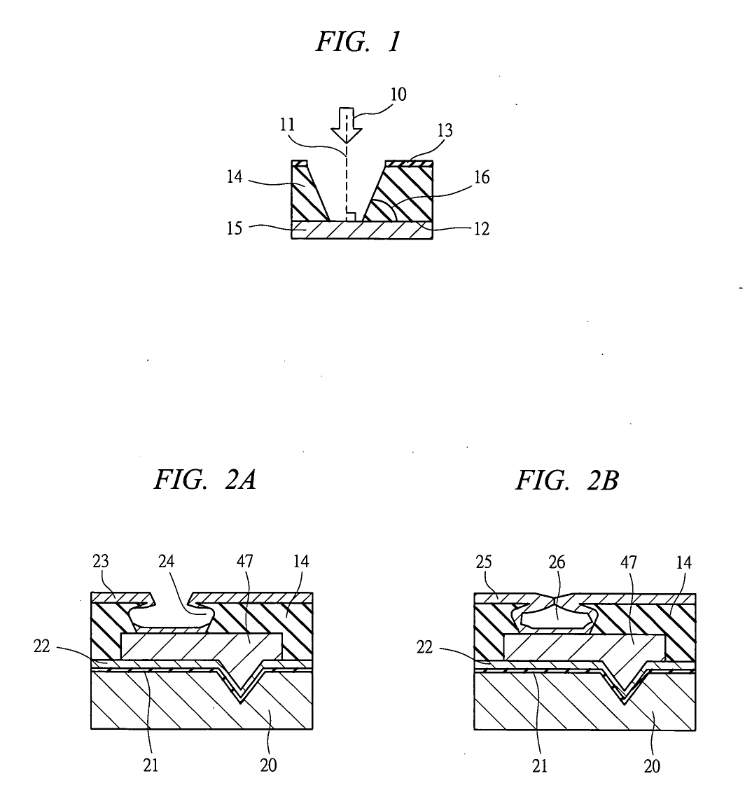

As an example of the laser to be used, ultraviolet laser is desired and the excimer laser is shown. For example, as shown in FIG. 1, when the excimer laser 10 is irradiated to a polyimide film serving as an object to be processed 14 on a wiring layer 15, the angle between a surface (vertical surface) 12 orthogonal to a laser beam axis 11 and a sidewall of a via (through hole) formed in the object to be processed 14 and the metal film mask 13, that is, a taper angle 16 can be controlled by the energy density on a processing surface. For example, in the case of the polyimide processing by the excimer laser with the energy density of 0.25 J/cm², the angle is about 65 degrees, and in the case of the polyimide processing by the excimer laser with the energy density of 0.20 J/cm², the angle is about 55 degrees. Consequently, when the via is formed in the polyimide film with a thickness of 14 μm and the energy density of the laser is 0.25 J/cm², the diameter of the via can be reduced to about 12 μm. Also, when the energy density of the laser is 0.20 J/cm², the diameter of the via can be reduced to about 20 μm. When the energy density is increased, the taper angle is also increased. However, since the so-called ablation phenomenon is dominant in the process by the excimer laser, the taper angle does not exceed 90 degrees or more. Furthermore, in the ablation processing, the resin is little carbonized and the occurrence of residues thereof can be inhibited. Therefore, the cleaning process of the residues is not necessary or can be reduced.

As an example of the dry etching, the reactive ion etching using oxygen gas as main reaction gas is shown. In this example, the oxygen ion bombardment or the oxidation reaction dominates the process. Also in this case, the taper angle is defined, and the via with the taper angle larger than 90 degrees, that is, the inverse taper angle can be formed. The shape of the via can be controlled depending on process conditions such as the gas pressure and the processing time so as to avoid the extreme taper angle. Therefore, the dry etching is the effective method for forming a via with a small diameter.

In the latter method, since the laser positioned by the optical component represented by galvano-mirror (galvanometer mirror) is used, the mask is unnecessary. Therefore, the cost can be reduced. In order to form the via with a minute diameter while controlling the occurrence of the residues due to the carbonization of resin, the process using the ultraviolet laser which is the ablation process is desired and the harmonic YAG laser is shown as the example. Also, even in the process using the carbon dioxide gas laser, the via with a small diameter can be formed if the residues are removed by the dry etching using the reaction gas. The via formed in the manner as described above does not have the extreme inverse taper angle.

If the taper angle is 90 degrees or more when forming the wiring of the via portion, the problems as follows occur. That is, when forming a metal film by a dry process such as sputtering, the sputter film 23 is not formed on the part 24 of the sidewall of the via as shown in FIG. 2A and the uniform film cannot be formed. Also, in the case of a wet process such as plating, the upper opening of the via is first closed as shown in FIG. 2B and the gap 26 in which the plating film 25 is not filled is formed in the via in some cases. Note that the reference numeral 20 denotes a silicon wafer, 21 denotes a silicon dioxide film, 22 denotes a foundation layer (also described as an underlying film), 47 denotes a contact terminal, and 14 denotes an object to be processed in FIG. 2A and FIG. 2B. The laser is the processing method effective to prevent the problems described above.

As the foundation layer 22 formed on the silicon dioxide film 21 of the silicon wafer 20 according to the present invention, one metal or alloy of metals selected from the group including gold, platinum, silver, rhodium, palladium, iridium, ruthenium, tungsten, chromium, copper and tin can be used.

Since the adhesion force of the gold film (foundation layer) 22 to the silicon dioxide film 21 on the silicon wafer 20, the contact terminal 47 and the polyimide (object to be processed) 14 is not strong, the gold film 22 can be easily separated from the silicon dioxide film 21, the contact terminal and the polyimide, which is the particularly effective characteristic thereof.

In the film (foundation layer) 22 obtained by forming a gold film and a tungsten film in this order on the silicon dioxide film 21, the adhesion force of the silicon dioxide film 21 on the silicon wafer to the gold film (part of foundation layer 22) and the adhesion force of the tungsten film (another part of foundation layer 22) to the contact terminal 47 and the polyimide (object to be processed) 14 are favorable, it is possible to stably manufacture the connecting apparatus. Also, gold is diffused into the tungsten film by the thermal treatment during the manufacturing process and the diffusion of gold reaches the interface with the contact terminals or the polyimide in the late stage of the process for manufacturing the semiconductor chip. Therefore, the separation between the silicon dioxide film and the contact terminal or the polyimide is facilitated.

In the film (foundation layer 22) obtained by forming chromium and copper in this order on the silicon dioxide film 21, the adhesion force of the silicon dioxide film 21 on the silicon wafer to the chromium film (part of foundation layer 22) and the adhesion force of the copper film (another part of foundation layer 22) to the contact terminal 47 and the polyimide (object to be processed) 14 are favorable, it is possible to stably manufacture the connecting apparatus.

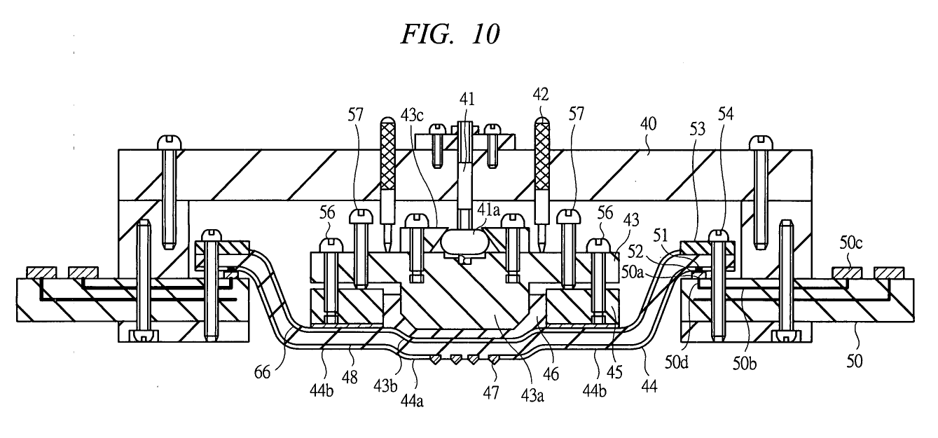

As the metal plate (metal material) for forming the contact terminal 47 and the wiring 48 of the wiring board for inspection 44 (refer to, for example, FIG. 10), the iron-based alloy containing at least nickel, chromium, cobalt or aluminum, the metal compound obtained by the copper clad of the iron-based alloy, tungsten, copper, molybdenum, tantalum, nickel and aluminum are available. Since the semiconductor chip 2 to be connected to the contact terminals 47 uses a low thermal expansion material such as silicon as the base material, it is desired that the wiring board for inspection 44 having the contact terminals 47 has a small thermal expansion coefficient. In particular, this characteristic is indispensable when it is used in the so-called burn-in test in which the semiconductor chip is connected while being heated. Consequently, the invar (36 wt % nickel-iron alloy) or 42 alloy (42 wt % nickel-iron alloy) is desirable as the metal material described above. In addition, since the electric resistance of copper and aluminum is low, copper and aluminum can be advantageously used as the ground layer of the wiring board for inspection 44 and also are superior in corrosion resistance.

With respect to the excessive load applied when connecting to the electrodes (electrode pad 3) to be inspected, an elastic resin (for example, polyimide 14) is provided adjacent to the contact terminals 47 and the load is applied to the elastic resin to push the contact terminals. By doing so, the better part of the load after connecting the electrodes can be absorbed by the elastic resin and the lifetime of the connecting apparatus can be extended.

The connecting apparatus according to the present invention is properly connected at low contact pressure simultaneously to the electrode pads 3 made of aluminum or solder, on the surface of which an oxide is formed, so as to be a stably low resistance in one or plural semiconductor chips 2 of a large number of semiconductor chips 2 in the form of a wafer on which minute electrode pads 3 are densely arranged at a narrow pitch. Therefore, it is possible to realize a tester which can cope with the increase of the density of the semiconductor chips to be inspected and the narrower pitch, can perform the inspection of a large number of chips connected simultaneously and can evaluate the electrical properties by the high-speed electric signal.

The embodiments of the present invention will be described below in detail with reference to the accompanying drawings. Note that the present invention is not limited to the embodiments below.

### First Embodiment

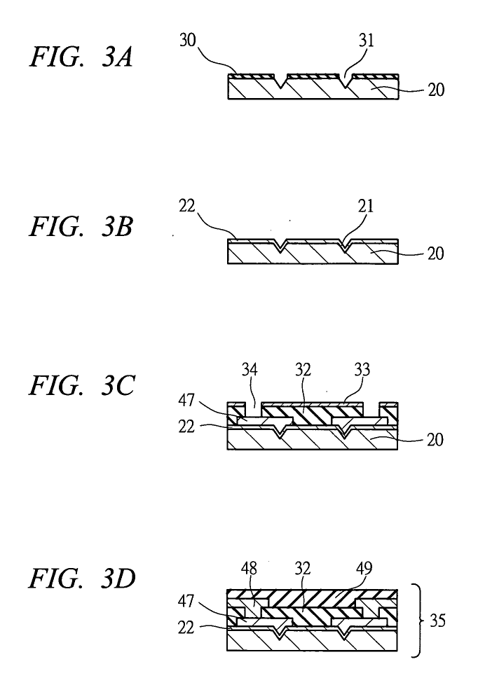

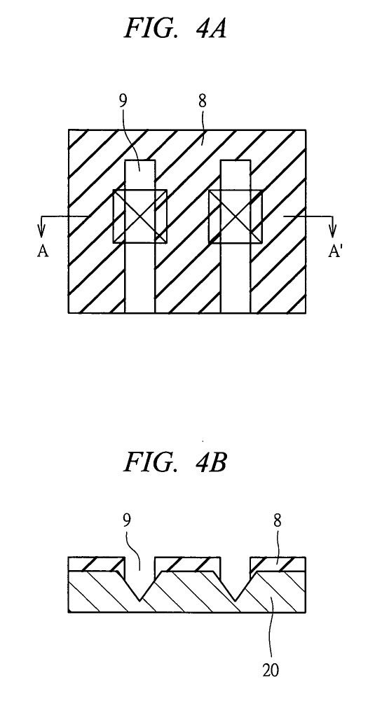

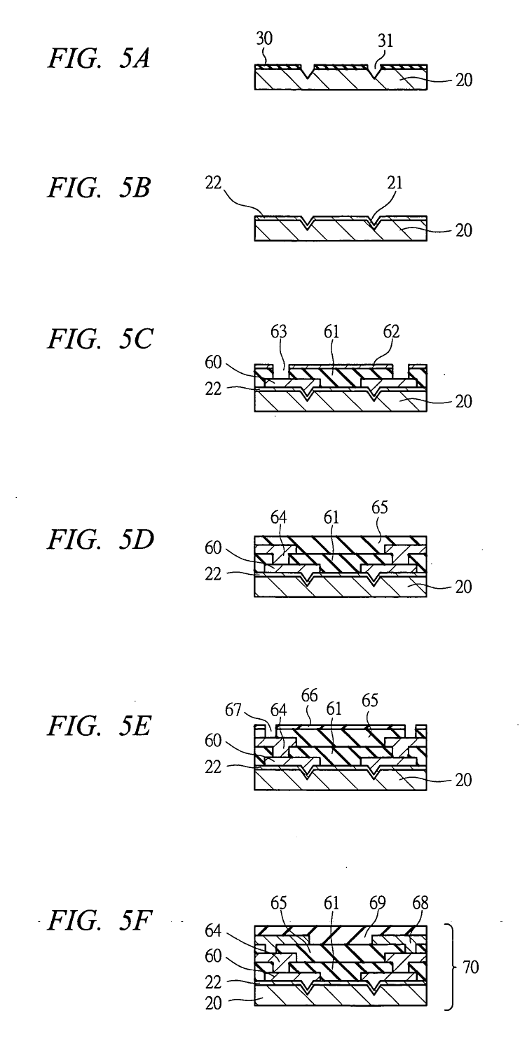

The manufacturing process of the connecting apparatus according to this embodiment will be described with reference to FIG. 3A to FIG. 3D and FIG. 4A and FIG. 4B. FIG. 3A to FIG. 3D are explanatory diagrams showing the manufacturing process of the connecting apparatus, and FIG. 4A and FIG. 4B are explanatory diagram showing the step of forming the contact terminals of the connecting apparatus (FIG. 4A is a top plan view showing the principal part and FIG. 4B is a cross-sectional view showing the principal part taken along the line A-A′ of FIG. 4A.).

As shown in FIG. 3A, a silicon dioxide film 30 with a thickness of 0.2 μm is formed on the (100) surface of the silicon wafer 20 made of single crystal silicon by holding the silicon wafer 20 in the oxygen atmosphere for 90 minutes in which the oxidation temperature is set at 1000° C. After coating a photosensitive resist with a thickness of 3 μm on the surface of the silicon dioxide film 30, the resist in the region in which the contact terminals are formed in the latter step is removed by the photolithography. By doing so, the resist having a plurality of openings of 29 μm square arranged at each 30 μm is formed. In this case, it is necessary to form the resist layer of at least 1 μm between the adjacent openings. Then, the silicon dioxide film at the openings are etched by dipping the wafer into the mixture of hydrofluoric acid and ammonium fluoride. Next, the photosensitive resist is removed, and the exposed silicon surface is anisotropically etched by potassium hydroxide solution heated to 90° C. with using the silicon dioxide film as a mask, thereby forming holes 31 in the shape of quadrangular pyramid having a bottom surface of 30 μm square (FIG. 3A). Then, the thermal oxidation process is performed again to form a silicon dioxide film 21 with a thickness of 0.2 μm (FIG. 3B). The process described above is identical to that described in Japanese Patent Laid-Open Publication No. 7-283280.

Next, after chromium (thickness: 0.5 μm) and copper (thickness: 1 μm) are laminated in this order by the sputtering to form a foundation layer 22, a photosensitive resist 8 with a thickness of 10 μm is coated and the resist of the contact terminal forming regions including the part of the quadrangular pyramid holes is removed by the photolithography. The pattern of the resist 8 is formed by removing the resist of the resist removal region 9 including the tips of the quadrangular pyramid holes 31 as shown in FIG. 4A and FIG. 4B.

The nickel plating is filled in the openings of the resist (e.g. the resist removal region 9 in FIG. 4B) to form the contact terminals 47 and then the resist is removed. Thereafter, a polyimide film 32 with a thickness of 15 μm serving as an insulating layer is formed. In FIG. 4B, for example, a metal projection as the principal part of the contact terminal 47 is formed in the resist removal region 9. Thus, a pyramidal hole of the silicon wafer 20 in which the metal projection is formed changes to a groove (grooves) thereof located around the metal projection. After the resist 8 is removed from the groove (grooves), an insulating material as the polyimide fills the groove (grooves). By doing so, the contact terminal having a part thereof (e.g. a peripheral part of a bottom portion of the quadrangular pyramid thereof) which is made of polyimide is formed.

After sputtering aluminum on the polyimide film 32, the aluminum film 33 is removed by the photolithography of photosensitive resist and the etching using mixed acid mainly containing phosphoric acid to form the openings in a part of the aluminum film 33 located above the contact terminal 47. Next, the excimer laser is irradiated to the polyimide film 32 until the nickel contact terminals 47 are exposed, and the via 34 which reaches the upper surface of the contact terminal 47 is formed in the polyimide film 32 (FIG. 3C). Thereafter, the silicon wafer 20 is dipped into the sodium hydroxide solution to remove the aluminum film 33.

Next, chromium and copper films are sequentially formed by the sputtering on the polyimide film 32 and on the sidewalls of the via 34, and then, wiring layers 48 are formed through the resist patterning, the copper plating and the pattern isolation by the so-called semi-additive method with using the chromium and copper films as seed films. Thereafter, a polyimide film 49 is formed to protect the wiring layers 48 (FIG. 3D).

In order to separate the wiring board for inspection having the contact terminals 47 from the silicon wafer 20, the silicon wafer 20 shown in FIG. 3D is dipped into potassium hydroxide solution at 90° C. to etch the silicon wafer 20. Next, the wiring board for inspection separated from the silicon wafer 20 is sequentially dipped into the mixed solution of hydrofluoric acid and ammonium fluoride, the potassium permanganate solution and the copper etching solution to remove the silicon dioxide film 21 and the chromium film and the copper film as the foundation layer 22.

In the connecting apparatus 35 manufactured through the process described above, the minute contact terminals 47 with the height of 23 μm and the bottom surface of 30 μm square are arranged at each 30 μm, and the contact terminals 47 are electrically connected to the wiring board for inspection (wiring layer 48) through the minute via 34. Also, since the foundation layer 22 composed of a chromium film and a copper film can enhance the adhesion force to the polyimide 32 and to the silicon wafer 20, the separation therebetween and the expansion of the polyimide film 32 during the step shown in FIG. 3C and FIG. 3D can be prevented.

### Second Embodiment

The manufacturing process of the connecting apparatus according to this embodiment will be described with reference to FIG. 5A to FIG. 5F. FIG. 5A to FIG. 5F are explanatory diagrams showing the manufacturing process of the connecting apparatus.

As shown in FIG. 5A, a silicon dioxide film 30 with a thickness of 0.2 μm is formed on the (100) surface of the silicon wafer 20 made of single crystal silicon by holding the silicon wafer 20 in the oxygen atmosphere for 90 minutes in which the oxidation temperature is set at 1000° C. After coating a photosensitive resist with a thickness of 3 μm on the surface of the silicon dioxide film 30, the resist is removed only from a part of the quadrangular pyramid by the photolithography in the same manner as described in the first embodiment as shown in FIG. 4A and FIG. 4B. By doing so, the resist having a plurality of openings of 24 μm square arranged at each 25 μm is formed. In this case, it is necessary to form the resist layer of at least 1 μm between the adjacent openings. Then, the silicon dioxide film at the openings are etched by dipping the wafer into the mixture of hydrofluoric acid and ammonium fluoride. Next, the photosensitive resist is removed, and the exposed silicon surface is anisotropically etched by potassium hydroxide solution heated to 90° C. with using the silicon dioxide film 30 as a mask, thereby forming holes 31 in the shape of quadrangular pyramid having a bottom surface of 30 μm square (FIG. 5A). Then, the thermal oxidation process of the single crystal silicon wafer 20 is performed again to form a silicon dioxide film 21 with a thickness of 0.2 μm (FIG. 5B).

Next, after chromium (thickness: 0.5 μm) and copper (thickness: 1 μm) are laminated in this order by the sputtering to form a foundation layer 22, a photosensitive resist with a thickness of 10 μm is coated and the resist of the contact terminal forming regions including the part of the quadrangular pyramid holes is removed by the photolithography. The pattern of the resist 8 is formed by removing the resist of the resist removal region 9 including the tips of the quadrangular pyramid holes 31 in the same manner as described in the first embodiment shown in FIG. 4A and FIG. 4B.

The nickel plating is filled in the openings of the resist to form the contact terminals 60 and then the resist is removed. Thereafter, a polyimide film 61 with a thickness of 10 μm serving as an insulating layer (1) is formed. By doing so, the contact terminal a part of which is made of polyimide is formed.

After sputtering aluminum on the polyimide film 61, the aluminum film 62 is removed by the photolithography of photosensitive resist and the etching using mixed acid mainly containing phosphoric acid to form the openings in a part of the aluminum film 62 located above the contact terminal 60. Next, the excimer laser is irradiated to the polyimide film 61 until the nickel contact terminals 60 are exposed, and the via 63 is formed in the polyimide film 61 (FIG. 5C). Thereafter, the single crystal silicon wafer 20 is dipped into the sodium hydroxide solution to remove the aluminum film 62.

Next, chromium and copper films are sequentially formed by the sputtering on the polyimide film 61 and on the sidewalls of the via 63, and then, wiring layers (1) 64 are formed through the resist patterning, the copper plating and the pattern isolation by the so-called semi-additive method with using the chromium and copper films as seed films.

Next, a polyimide film 65 with a thickness of 10 μm serving as an insulating layer (2) is formed on the insulating layer (1) (polyimide film 61) (FIG. 5D). Further, after sputtering aluminum on the polyimide film, the aluminum film 66 is removed by the photolithography of photosensitive resist and the etching using mixed acid mainly containing phosphoric acid to form the openings in a part located above the wiring layer 64. Next, the excimer laser is irradiated to the insulating layer (2) (polyimide film 65) until the wiring layer (1) 64 is exposed, and the via 67 is formed in the polyimide film 65 (FIG. 5E). Thereafter, the single crystal silicon wafer 20 is dipped into the sodium hydroxide solution to remove the aluminum film 66.

Next, chromium and copper films are sequentially formed by the sputtering on the polyimide film 65 and on the sidewalls of the via 67, and then, wiring layers (2) 68 are formed through the resist patterning, the copper plating and the pattern isolation by the so-called semi-additive method with using the chromium and copper films as seed films. Thereafter, a polyimide film 69 is formed to protect the wiring layers 68 (FIG. 5F).

In order to separate the wiring board for inspection having the contact terminals 60 from the silicon wafer 20, the silicon wafer 20 shown in FIG. 5F is dipped into potassium hydroxide solution at 90° C. to etch the silicon wafer 20. Next, the wiring board for inspection separated from the silicon wafer 20 is sequentially dipped into the mixed solution of hydrofluoric acid and ammonium fluoride, the potassium permanganate solution and the copper etching solution to remove the silicon dioxide film 21 and the chromium film and the copper film as the foundation layer 22.

In the connecting apparatus 70 manufactured through the process described above, the minute contact terminals 60 with the height of 23 μm and the bottom surface of 30 m square are arranged at each 25 μm, and the contact terminals 60 are electrically connected to the wiring board for inspection (wiring layers 64 and 68) through the minute via 63 and 67. Also, since the two wiring layers are formed to increase the width of the wiring, the resistance in the wiring can be reduced.

### Third Embodiment

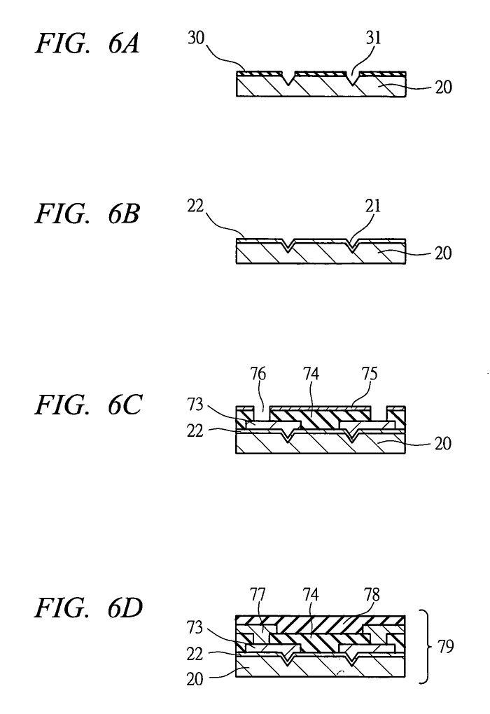

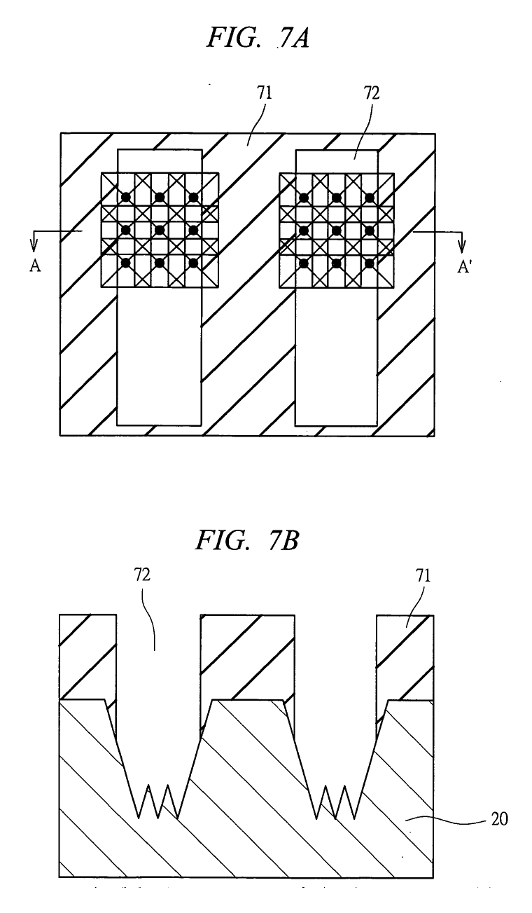

The manufacturing process of the connecting apparatus according to this embodiment will be described with reference to FIG. 6A to FIG. 6D and FIG. 7A and FIG. 7B. FIG. 6A to FIG. 6D are explanatory diagrams showing the manufacturing process of the connecting apparatus and FIG. 7A and FIG. 7B are explanatory diagram showing the step of forming the contact terminal of the connecting apparatus (FIG. 7A is a top plan view showing the principal part and FIG. 7B is a cross-sectional view taken along the line A-A′ of FIG. 7A.).

As shown in FIG. 6A, a silicon dioxide film 30 with a thickness of 0.2 μm is formed on the (100) surface of the silicon wafer 20 made of single crystal silicon by holding the silicon wafer 20 in the oxygen atmosphere for 90 minutes in which the oxidation temperature is set at 1000° C. After coating a photosensitive resist with a thickness of 3 μm on the surface of the silicon dioxide film 30, the resist in the region in which the contact terminals are formed in the latter step is removed by the photolithography. In the pattern of the contact terminals, nine squares 5 μm on a side (region in which the connecting terminal in the shape of quadrangular pyramid is located) are arranged at 1 μm pitch in lengthwise and crosswise and the nine squares form a group (refer to FIG. 7A). The groups are juxtaposed at 30 μm pitch. At this time, it is necessary to leave the resist layer of at least 1 μm between the adjacent openings of the resist layer. Then, the single crystal silicon wafer 20 is dipped into the mixture of hydrofluoric acid and ammonium fluoride to etch the silicon dioxide film 30 exposed in the openings of the resist layer. Next, after the photosensitive resist is removed, the exposed silicon surface is anisotropically etched by potassium hydroxide solution heated to 90° C. with using the silicon dioxide film 30 as a mask, thereby forming holes 31 in the shape of quadrangular pyramid having a bottom surface of 30 μm square (FIG. 6A). Then, the thermal oxidation process of the single crystal silicon wafer 20 is performed again to form a silicon dioxide film 21 with a thickness of 0.2 μm (FIG. 6B).

Next, after chromium (thickness: 0.5 μm) and copper (thickness: 1 μm) are laminated in this order by the sputtering to form a foundation layer 22, a photosensitive resist with a thickness of 10 μm is coated and the resist of the contact terminal forming regions including the part of the quadrangular pyramid holes is removed by the photolithography. The pattern of the resist 71 is formed by removing the resist of the resist removal region 72 including the tips of the nine quadrangular pyramid (shown by black circles) as shown in FIG. 7A and FIG. 7B.

The nickel plating is filled in the openings of the resist to form the contact terminals 73 and then the resist is removed. Thereafter, a polyimide film 74 with a thickness of 15 μm serving as an insulating layer is formed. By doing so, the openings of 30 μm square are arranged at each 30 μm to form a plurality of terminals and each of the terminals has nine tip portions. A part of the contact terminals 73 is made of polyimide.

After sputtering aluminum on the polyimide film 74, the aluminum film 75 is removed by the photolithography of photosensitive resist and the etching using mixed acid mainly containing phosphoric acid to form the openings in a part of the aluminum film 75 located above the contact terminal 73. Next, the excimer laser is irradiated to the polyimide film 74 until the nickel contact terminals 73 are exposed, and the via 76 is formed in the polyimide film 74 (FIG. 6C). Thereafter, the single crystal silicon wafer 20 shown in FIG. 6C is dipped into the sodium hydroxide solution to remove the aluminum film 75.

Next, chromium and copper films are sequentially formed by the sputtering on the polyimide film 74 and on the sidewalls of the via 76, and then, wiring layers 77 are formed through the resist patterning, the copper plating and the pattern isolation by the so-called semi-additive method with using the chromium and copper films as seed films. Thereafter, a polyimide film 78 is formed to protect the wiring layers 77 (FIG. 6D).

In order to separate the wiring board for inspection having the contact terminals 73 from the silicon wafer, the single crystal silicon wafer 20 shown in FIG. 6D is dipped into potassium hydroxide solution at 90° C. to etch the silicon wafer 20. Next, the wiring board for inspection separated from the silicon wafer 20 is sequentially dipped into the mixed solution of hydrofluoric acid and ammonium fluoride, the potassium permanganate solution and the copper etching solution to remove the silicon dioxide film 21 and the chromium film and the copper film as the foundation layer 22.

In the connecting apparatus 79 manufactured through the process described above, the minute contact terminals 73 with the height of 23 μm and the bottom surface of 30 μm square are arranged at each 30 μm, and the contact terminals 73 are electrically connected to the wiring board for inspection (wiring layer 77) through the minute via 76. Also, since the foundation layer 22 composed of a chromium film and a copper film can enhance the adhesion force to the polyimide 74 and to the silicon wafer 20, the separation therebetween and the expansion of the polyimide film 74 during the step shown in FIG. 6C and FIG. 6D can be prevented.

Also, since the contact terminal 73 has nine tip portions, the contact area to the electrode pads (object to be inspected) can be increased about nine times as large as that of the contact terminal with a single tip portion. Note that the number of tip portions of the contact terminal 73 is not limited to nine, but may be any plural number.

### Fourth Embodiment

In this embodiment, after forming a quadrangular pyramid hole 31 and the silicon dioxide film 21 on the main surface of the silicon wafer 20, a gold film and a tungsten film are sputtered in this order to form the foundation layer 22. Except for the process described above, the connecting apparatus 35 (70, 79) is manufactured through the same process as those of the first to third embodiments.

In the foundation layer 22 obtained by forming gold and tungsten films in this order, since the adhesion force of the silicon dioxide film 21 on the silicon wafer 20 to the gold film (part of foundation layer 22) and the adhesion force of the tungsten film (another part of foundation layer 22) to the contact terminal 47 and the polyimide film 32 are favorable, it is possible to stably manufacture the connecting apparatus 35. Also, the gold is diffused into the tungsten film by the thermal treatment during the manufacturing process and the diffusion of gold reaches the interface with the contact terminals 47 or the polyimide film 32 in the late stage of the process for manufacturing the semiconductor chip. Therefore, the separation between the silicon dioxide film 21 and the contact terminal 47 or the polyimide film 32 is facilitated. Consequently, the occurrence of defects in the manufacturing process of the connecting apparatus 35 can be reduced.

### Fifth Embodiment

In this embodiment, after forming a quadrangular pyramid hole 31 and the silicon dioxide film 21 on the main surface of the silicon wafer 20, a gold film with a thickness of 1 μm is laminated by the sputtering to form the foundation layer 22. Except for the process described above, the connecting apparatus 35 (70, 79) is manufactured through the same process as those of the first to third embodiments.

Since the adhesion force of the gold film to the silicon dioxide film 21 on the silicon wafer 20 or to the contact terminal 47 and the polyimide film 32 is not so strong, the separation between the silicon dioxide film 21 and the contact terminal 47 or the polyimide film 32 is facilitated, which is the particularly effective characteristic thereof.

### Sixth Embodiment

In this embodiment, the reactive ion etching using oxygen as main reaction gas is used instead of the excimer laser in the step of forming the via 34 (63, 67, 76). Except for the process described above, the connecting apparatus 35 (70, 79) is manufactured through the same process as those of the first to third embodiments.

In the case where the reaction gas is used, the via 34 with the taper angle of about 90 degrees can be formed. Therefore, the via 34 formed in the polyimide film 32 can be miniaturized to about 10 μm square. Furthermore, owing to the miniaturization of the via, the connecting apparatus 35 in which the interval between the contact terminals 47 is further reduced can be obtained.

### Seventh Embodiment

In this embodiment, the aluminum film 33 is not formed on the polyimide film 32, and the harmonic YAG laser is irradiated to the polyimide film 32 to form the via 34 therein. Except for the process described above, the connecting apparatus 35 (70, 79) is manufactured through the same process as those of the first to third embodiments.

In this case, since the mask of the aluminum film 33 is unnecessary, the connecting apparatus 35 which is identical to those of the first to fifth embodiments can be manufactured at low cost.

### Eighth Embodiment

This embodiment relates to the semiconductor chip inspecting apparatus using the connecting apparatus manufactured in the first to seventh embodiments described above and the method of manufacturing a semiconductor device.

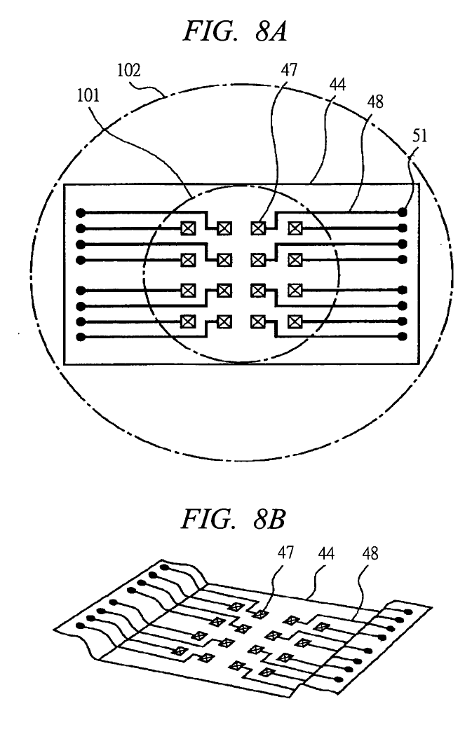

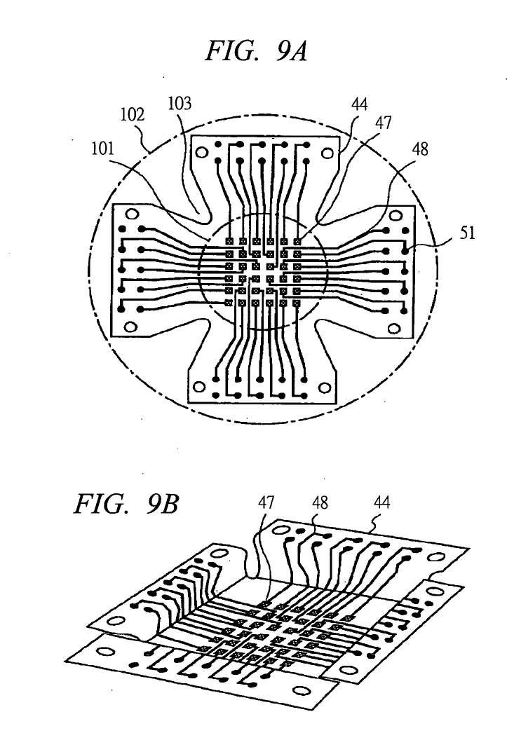

The arrangement of the contact terminals in the connecting apparatus and the wiring of the wiring board for inspection are changed depending on the arrangement of the object to be inspected, for example, the arrangement of the electrode pads of the semiconductor chip. FIGS. 8A and 8B and FIGS. 9A and 9B show the first and second examples of the arrangement. FIG. 8A is a plan view showing the first example and FIG. 8B is a perspective view showing the state of the bent wiring board for inspection on which the wiring of FIG. 8A is provided. FIG. 9A is a plan view showing the second example and FIG. 9B is a perspective view showing the state of the bent wiring board for inspection on which the wiring of FIG. 9A is provided. Note that, in these drawings, the number of the contact terminals and the wirings are reduced for the simplification of the drawings and description and the density thereof is also reduced. In a practical case, a larger number of contact terminals are provided and more densely arranged.

As shown in FIGS. 8A and 8B and FIGS. 9A and 9B, in the connecting apparatus, on the wiring board for inspection 44 using a polyimide film as a base material, the contact terminals 47 arranged at positions corresponding to the electrode pads 3 of the object to be inspected are connected to one ends, the other ends are electrodes 51 provided in the peripheral region of the wiring board for inspection, and the wiring layer (wirings) 48 for connecting the contact terminals 47 and the electrodes 51 are formed. The wirings 48 can be provided in various manners. For example, the wirings can be extended in one direction or extended radially. More specifically, in the first example shown in FIGS. 8A and 8B, the wiring board for inspection 44 is formed in a rectangular shape, and the electrodes 51 are arranged on both side portions. In the second example shown in FIGS. 9A and 9B, the wiring board for inspection 44 is formed in a cross shape, and the wirings 48 are extended to the electrodes 51 provided on each side thereof.

For example, in the case where the object to be inspected is the electrode pads on the surface of the semiconductor chip formed on the wafer, the connecting apparatus for transmitting the electric signal to the main unit of the inspecting apparatus is manufactured by using a contact terminal forming member 102 such as a silicon wafer which is one size larger than the region 101 in which the semiconductor chips are formed on the wafer as shown in FIG. 8A and FIG. 9A in accordance with the method described in the first to seventh embodiments. Note that FIG. 8B and FIG. 9B show the state where the wiring board 44 is bent so as to enclose the region 101 in which the contact terminals 47 are formed within a polygon. Also, a reference numeral 103 in FIG. 9A denotes a cut line formed on the wiring board for inspection 44 (base material thereof) when the wirings are provided radially.

Note that the case where the electrode pads of all semiconductor chips formed on a wafer which are the objects to be inspected are collectively contacted has been described in this embodiment. However, the present invention is not limited to this. For example, as the connecting apparatus for individually inspecting the semiconductor chip or the connecting apparatus for inspecting arbitrary number of semiconductor chips at the same time, the wiring board for inspection with a size smaller than the wafer size can be manufactured.

FIG. 10 is a diagram showing the principal part of the case where the connecting apparatus according to the present invention is mounted in the inspection connecting system. Note that, in FIG. 10, the connecting apparatus in the first embodiment is mounted in the inspection connecting system. However, the connecting apparatus in the second and third embodiments can be mounted in the same manner.

The inspection connecting system in which the connecting apparatus is mounted comprises an upper clamping plate 40, a center pivot 41 fixed to the plate 40, which is a support axis having a sphere 41a at the lower portion thereof, spring probes 42 as pressing force applying means provided symmetrically around the center pivot 41 and applying a constant pressing force for the upward and downward displacement, a pressing piece 43 held so as to be tilted by the tilt 43c to the center pivot 41 and to which the pressing force-of a small load (about 3 to 50 mN per pin) is applied from the spring probes 42, the wiring board for inspection 44, a frame 45 fixed to the wiring board for inspection 44, a buffer layer 46 provided between the wiring board for inspection 44 and the pressing piece 43, and the contact terminals 47 provided on the wiring board for inspection 44. The reason why the spring probes 42 are used to apply the pressing force to the pressing piece 43 is to obtain the constant pressing force of small load for the displacement of the tips of the spring probes 42. Therefore, it is not always necessary to use the spring probes 42.

The upper clamping plate 40 is mounted on a wiring board 50. The wiring board 50 is made of, for example, a resin material such as polyimide resin or glass epoxy resin, and it has an internal wiring 50b and connecting terminals 50c. The electrode 50a of the wiring board 50 is composed of, for example, a via 50d connected to a part of the internal wiring 50b. The wiring board 50 is fixed to the wiring board for inspection 44 by sandwiching the wiring board for inspection 44 between the wiring board 50 and holding members 53 with screws 54. The wiring board for inspection 44 has a peripheral part outwardly extending over the frame 45 and the extended part is gently bent on the outside of the frame 45 and is fixed to the wiring board 50. At this time, the wiring 48 of the wiring board for inspection 44 is electrically connected to the electrode 50a provided on the wiring board 50. The connection therebetween is made by directly applying a pressure to the electrodes 51 and 50a or by using an anisotropic conductive sheet 52 or solder.

As the buffer layer 46, an elastic material is desirably used, and silicon rubber is shown as an example of the polymeric material with the rubber elasticity. Also, as the buffer layer 46, the structure in which the pressing piece 43 is movably sealed to the frame 45 and air is supplied into the gap of the sealing can also be used. In addition, the buffer layer 46 can be omitted if the height of the contact terminals 47 can be made uniform. Note that, in FIG. 10, the contact terminals 47 and the wirings 48 corresponding to only two contact terminals are shown for the simplification of the description. In a practical case, however, a large number of contact terminals 47 and the wirings 48 are provided.

An object of the connecting apparatus according to the present invention is to properly connect the contact terminals at small load (3 to 50 mN per pin) simultaneously to the electrode pads 3 made of aluminum or solder, on the surface of which an oxide is formed, so as to be a stably low resistance of about 0.05 to 0.1 Ω, in one or plural semiconductor chips of a large number of semiconductor chips in the form of wafer. By doing so, the scrub operation required in the conventional technology becomes unnecessary and the problems of the indentations and the electrode waste due to the scrub operation can be prevented.

More specifically, in the wiring board for inspection 44, the tip portions of the contact terminals 47 arranged so as to correspond to the arrangement of the electrode pads 3 are made sharp, and the region 44a inside the peripheral region 44b in which the contact terminals 47 are arranged is pressed by a lower surface 43b with a precise flatness of a protruding portion 43a formed in the lower part of the pressing piece 43 via the buffer layer 46 so that the region 44a is projected from the peripheral region 44b supported by the frame 45. By doing so, the sagging of the wiring board for inspection is removed. Then, the sharp tips of the contact terminals 47 arranged in the projected region 44a are vertically pressed at small load to the electrode pads 3 made of aluminum or solder. By doing so, the contact terminals 47 easily pass through the oxide formed on the surface of the electrode pads 3 and are brought into contact with the metal conductor material of the electrodes, and the preferable contact therebetween can be secured at a stably low resistance value.

In particular, the region 44a inside the peripheral region 44b in which the contact terminals 47 are arranged is pressed by a lower surface 43b with a precise flatness of a protruding portion 43a formed in the lower part of the pressing piece 43 via the buffer layer 46 so that the region 44a is projected from the peripheral region 44b supported by the frame 45. By doing so, the sagging of the wiring board for inspection is removed. Also, the tips of a large number of contact terminals 47 have the same height in accordance with the flatness of the lower surface 43b of the protruding portion 43a.

Note that the projecting amount of the pressing piece 43 to the wiring board for inspection 44 in the region 44a is defined in accordance with a protrusion of a screw (clinchers) 57 which is screwed up at the left, right, back and forth of the pressing piece 43 around the center pivot to be adjustable from a lower surface of the pressing piece 43 in the peripheral region 44b. More specifically, screws 56 inserted into the holes formed at the left, right, back and forth in the holding member around the center pivot 41 are screwed to the frame 45 to let down the protruding portion 43a of the pressing piece 43. By doing so, the lower ends of the screws 57 attached to the pressing piece 43 with a specified protruding amount are brought into contact with the upper surface of the frame 45 to which the peripheral region 44b of the region 44a in the wiring board for inspection 44 is fixed. In this manner, the region 44a in which a large number of contact terminals 47 are arranged is projected through the buffer layer 46, and the sagging of the wiring board for inspection can be removed.

Through the process described above, the sharp tip portions of the contact terminals can have the same height with the accuracy of ±2 μm over a large number of contact terminals 47. Note that Japanese Patent Laid-Open Publication No. 2002-139554 (and the counterpart U.S. Pat. Nos. 6,305,230 and 6,759,258) describes some inspection connecting systems other than that described above, and any of them can be used.

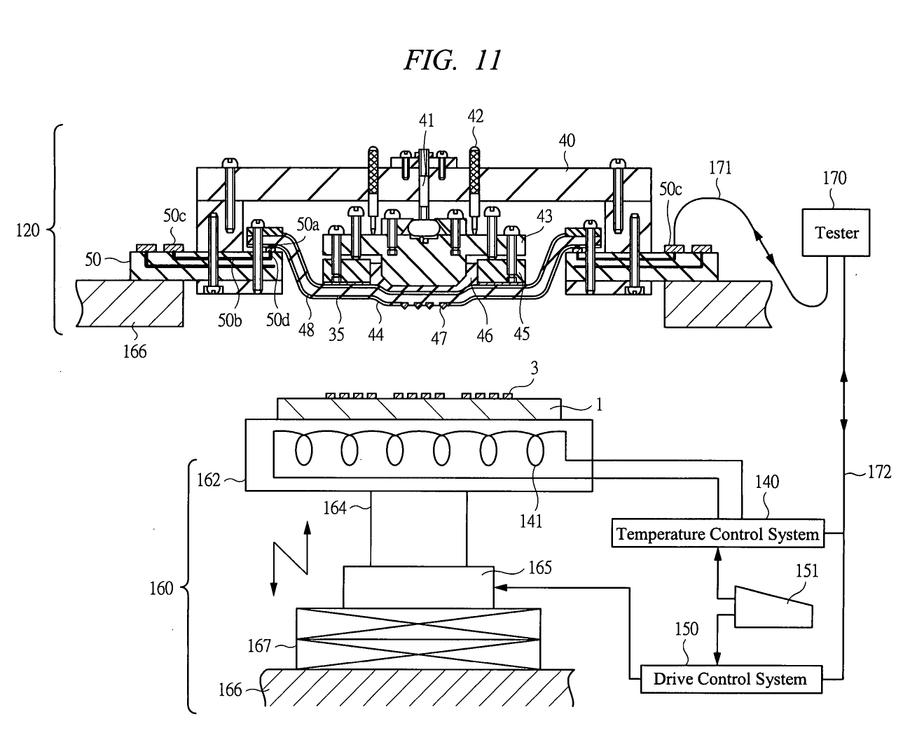

The inspection of the electrical properties for the semiconductor chip to be inspected by using the connecting apparatus according to the present invention will be described with reference to FIG. 11. FIG. 11 is an explanatory diagram showing the overall structure of the semiconductor chip inspecting apparatus according to the present invention including the structure of FIG. 10.

The semiconductor chip inspecting apparatus is constituted as the wafer connecting apparatus in the manufacture of a semiconductor device. This inspecting apparatus comprises a sample support system 160 for supporting the wafer 1 to be inspected, an inspection connecting system 120 which is brought into contact with the electrode pads 3 of the wafer 1 to transmit electric signals, a drive control system 150 for controlling the operation of the sample support system 160, a temperature control system1 140 for controlling the temperature of the wafer 1, and a tester 170 for inspecting the electrical properties of the semiconductor chip 2. A large number of semiconductor ships 2 are arranged on the wafer 1 and a plurality of minute electrode pads 3 to be connected to the outside are arranged at a narrow pitch on the surface of each semiconductor chip 2.

The sample support system 160 is provided with a sample stage 162 placed almost horizontally for mounting the wafer 1, an elevation axis 164 provided vertically so as to support the sample stage 162, an elevation drive unit 165 which moves up and down the elevation axis 164, and an X-Y stage 167 which supports the elevation drive unit 165. The X-Y stage 167 is fixed onto a chassis 166. The elevation drive unit 165 is composed of, for example, a stepping motor or the like. A turning mechanism is provided in the sample stage 162, which enables the rotational displacement of the sample stage 162 within the horizontal surface. The position of the sample stage 162 is determined by combining the operations of the X-Y stage 167, the elevation drive unit 165, and the turning mechanism.

The inspection connecting system 120 is placed above the sample stage 162. More specifically, the connecting apparatus 35 and the wiring board 50 shown in FIG. 11 are positioned in parallel with the sample stage 162 and are opposed to the sample stage 162. Note that, in this embodiment, the connecting terminal 50c is formed of a coaxial connector. The inspection connecting system 120 is connected to the tester 170 via a cable 171 connected to the connecting terminal 50c.

The drive control system 150 is connected to the tester 170 via a cable 172. Also, the drive control system 150 sends a control signal to each drive unit of the sample support system 160 to control the operation thereof. More specifically, the drive control system 150 is provided with a computer therein and controls the operation of the sample support system 160 in accordance with the progress information of the test operation of the tester 170 transmitted through the cable 172. Also, the drive control system 150 is provided with an operation unit 151 and receives the inputs of various instructions regarding the drive control, for example, the instruction for the manual operation.

The sample stage 162 is provided with a temperature controller 141 for heating purpose so as to perform the burn-in test of the semiconductor chip 2. The temperature control system 140 controls the temperature of the wafer 1 mounted on the sample stage 162 by controlling the temperature controller 141 of the sample stage 162. Also, the temperature control system 140 is provided with an operation unit 151 to receive the instruction for the manual operation regarding the temperature control.

The operation of the inspecting apparatus will be described below. First, the wafer 1 to be inspected is positioned and mounted on the sample stage 162. The optical images of a plurality of reference marks formed above the wafer 1 are taken by an imaging device such as an image sensor or a TV camera to detect the positions of the plurality of reference marks based on the obtained image signals. Based on the information of the detected positions of the reference marks, the information of the arrangement of the semiconductor chips 2 and that of the electrode pads 3 on the semiconductor chips 2 are confirmed in accordance with the type of the wafer 1, and the two-dimensional positional information in the whole electrode pad group is calculated.

Furthermore, the optical images of the specific contact terminals in a large number of contact terminals 47 formed on the wiring board for inspection or the optical images of a plurality of reference marks formed above the wiring board for inspection are taken by an imaging device such as an image sensor or a TV camera to detect the positions of the specific contact terminals or the plurality of reference marks. Based on the information described above, the two-dimensional positional information in the whole contact terminal group is calculated.

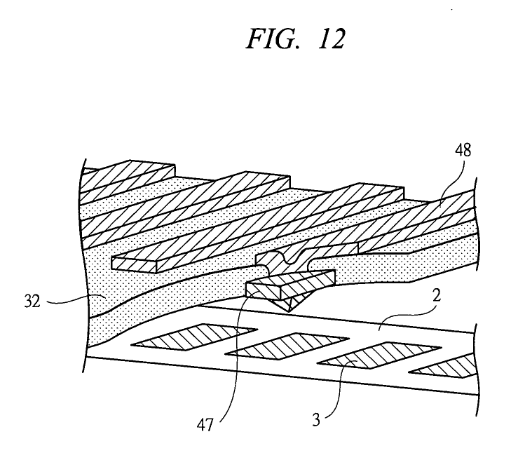

The drive control system 150 calculates the difference between the two-dimensional positional information in the whole contact terminal group and the two-dimensional positional information in the whole electrode pad group, and it controls the X-Y stage 167 and the turning mechanism based on the difference so that the group of the electrode pads 3 formed on a plurality of semiconductor chips arranged on the wafer 1 is positioned just below the group of a large number of contact terminals 47 provided in the connecting apparatus 35. Thereafter, the drive control system 150 actuates the elevation drive unit 165 based on the gap between the surface of the region 44a of the wiring board for inspection and the wafer 1 measured by a gap sensor provided on the sample stage 162, and it elevates the sample stage 162 until the whole surface of a large number of electrode pads 3 pushes up the contact terminals by several μm from the point where the surfaces of the electrode pads 3 come into contact with the tips of the contact terminals. FIG. 12 shows the appearance of the inspection for the semiconductor chip 2 on which the electrode pads 3 are arranged, in which the inspecting apparatus is used.

In this manner, parallelism of all of the number of the contact terminal 47 is corrected in accordance with a whole surface of the number of the electrode pads 3. Also, the variation in height of the contact terminals 47 is absorbed by the buffer layer 46, and the contact terminals 47 are pressed into the electrode pads 3 by the small load (about 3 to 50 mN per pin), and thus, each of the contact terminals 47 is connected to each of the electrode pads 3 at a low resistance (0.01 to 0.1 Ω).

When the burn-in test of the semiconductor chip 2 is performed in this state, the temperature control system 140 controls the temperature controller 141 of the sample stage 162 so as to control the temperature of the wafer 1 mounted on the sample stage 162. Therefore, the wiring board for inspection 44 is mainly made of flexible and preferably heat-resistant resin. In this embodiment, polyimide resin is used.

The operation power and the operation test signals are transmitted between the semiconductor chips 2 formed on the wafer 1 and the tester 170 through the cable 171, the wiring board 50, the wiring board for inspection 44 and the contact terminals 47, and the electrical properties of the semiconductor wafer 2 are determined. The series of operations described above are executed for each of the semiconductor chips 2 formed on the wafer 1 and the electrical properties and the like are determined.

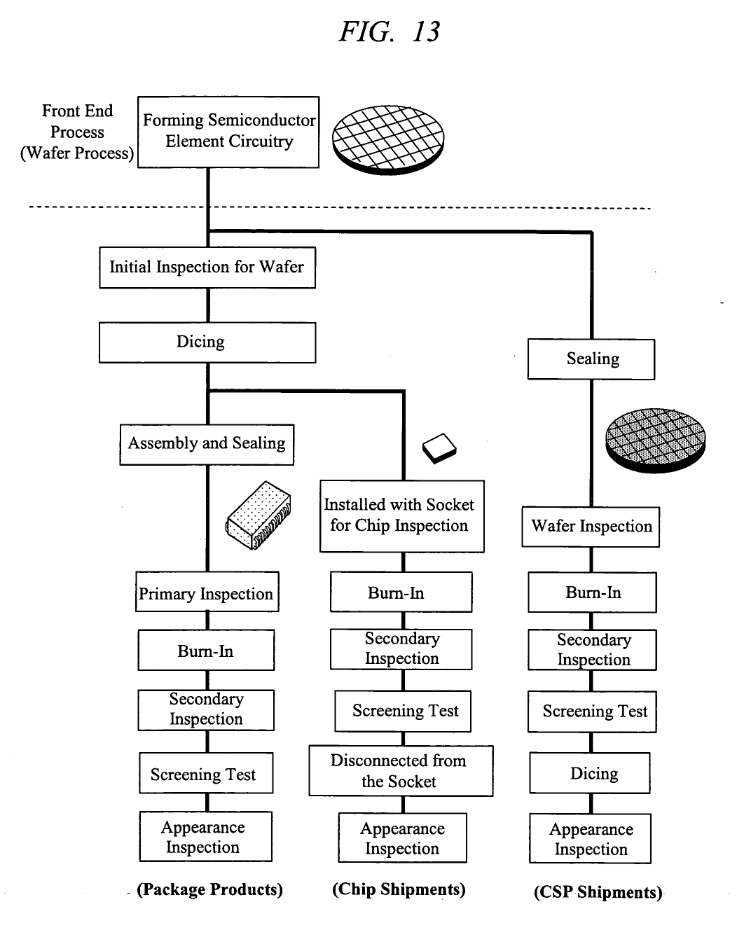

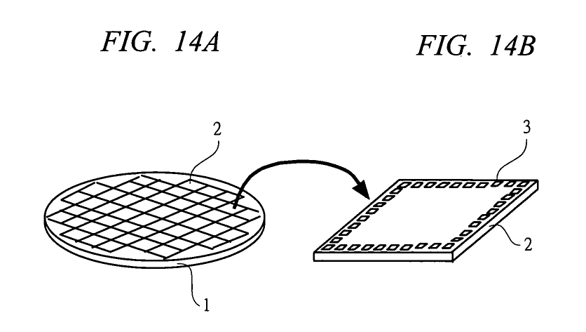

Lastly, a representative example of the method of manufacturing a semiconductor device by using the connecting apparatus described above will be described with reference to FIG. 13. FIG. 13 is an explanatory diagram showing the method of manufacturing a semiconductor device.

For example, the method of manufacturing a semiconductor device according to the present invention includes a step of fabricating circuits on a wafer to form semiconductor elements (forming semiconductor element circuitry), a step of sealing the wafer with resin or the like (sealing), a step of collectively inspecting the electrical properties of a plurality of semiconductor devices formed on the sealed wafer (wafer inspection), a step of inspecting the electrical properties at high temperature (burn-in test), a secondary inspection, a screening test, a step of cutting the wafer to separate each of the semiconductor elements (dicing) and an appearance inspection. Through the steps described above, they are shipped as the CSP products (CSP: an abbreviation of Chip Size Package or Chip Scale Package). Of the steps described above, the inspecting apparatus according to the present invention is used in the burn-in test, the wafer inspection, the secondary inspection, the screening test and the like.

Note that, even in the case where the CSP products are shipped as the full wafer without cutting the wafer or as the divided wafer obtained by cutting the wafer into quarter pieces, the method described above is similarly applicable.

Also, the method of manufacturing a semiconductor device according to the present invention includes a step of fabricating circuits on a wafer to form semiconductor elements (forming semiconductor element circuitry), a step of collectively inspecting the electrical properties of a plurality of semiconductor elements in a wafer level (initial inspection for the wafer), a step of cutting the wafer to separate each of semiconductor elements (dicing), a step of sealing the semiconductor elements with resin (assembly and sealing), a primary inspection, a step of evaluating the electrical properties at high temperature (burn-in), a screening test and an appearance inspection. Through the steps described above, they are shipped as the package products (Packaged articles). Of the steps described above, the inspecting apparatus according to the present invention is used in the initial inspection for wafer and the like.

Furthermore, the method of manufacturing a semiconductor device according to the present invention includes a step of fabricating circuits on a wafer to form semiconductor elements (forming semiconductor element circuitry), a step of collectively inspecting the electrical properties of a plurality of semiconductor elements in a wafer level (initial inspection for the wafer), a step of cutting the wafer to separate each of semiconductor elements (dicing), a step of evaluating the electrical properties of the semiconductor element installed with socket for chip inspection at high temperature (burn-in), a secondary inspection, a screening test and an appearance inspection of the semiconductor element disconnected from the socket. Through the steps described above, they are shipped as the chip shipments. Of the steps described above, the inspecting apparatus according to the present invention is used in the initial inspection for wafer and the like.

As described above, according to this embodiment, the connecting apparatus for contacting with the electrode pads, which are densely arranged at a narrow pitch because of the increase of the integration degree of the semiconductor chip, to inspect the semiconductor chip is manufactured by electrically connecting, via metal junction, minute contact terminals with sharp tips densely arranged at a narrow pitch equal to that of the electrode pads to wirings of a wiring board for inspection in which via interconnect lines are densely arranged without any multilayer interconnection. Also, a plurality of contact terminals are arranged for one electrode pad. Consequently, the effects described below can be obtained.

(1) Since a group of contact terminals are simply pressed at a low contact pressure (about 3 to 50 mN per pin) to electrode pads such as aluminum or solder of objects to be inspected on which an oxide is formed, the stable connection with low resistance of about 0.05 to 0.1 Ω can be realized without damages due to the indentation and the electrode wastes.

(2) Since a large number of contact terminals can be easily arranged on the wiring board for inspection, the electrode pads of one or plural semiconductor chips of a large number of semiconductor chips arranged on a wafer can be surely connected at the same time, and the electrical properties of each semiconductor chip can be evaluated.

(3) It is possible to transmit the high-frequency electric signals (high frequency of about 100 MHz to several 10 GHz).

(4) The electrical property evaluation at high temperature such as the burn-in test can be performed, and it is possible to evaluate the electrical properties of the semiconductor chip in which the pitch becomes narrower and the density of the electrode pads is increased.

In the foregoing, the invention made by the inventors of the present invention has been concretely described based on the embodiments. However, it is needless to say that the present invention is not limited to the foregoing embodiments and various modifications and alterations can be made within the scope of the present invention.

The present invention is applied to connecting apparatus used to inspect a semiconductor chip, semiconductor chip inspecting apparatus using the connecting apparatus, and a method of manufacturing a semiconductor device using them. More particularly, the present invention can be effectively applied to a connecting technology for a semiconductor chip which transmits high-speed signals, and in which minute electrodes are arranged at a narrow pitch or a plurality of electrode pads can be connected at the same time.

While we have shown and described several embodiments in accordance with the present invention, it is understood that the same is not limited thereto but is susceptible of numerous changes and modifications as known to those skilled in the art, and we therefore do not wish to be limited to the details shown and described herein but intend to cover all such changes and modifications as are encompassed by the scope of the appended claims.

What is claimed is:

1. A connecting apparatus electrically contacting with an object to be inspected and inputting and outputting electrical signals, comprising:
contact terminals electrically contacting with said object to be inspected;
an insulating layer having said contact terminals provided on one surface thereof; and
a wiring layer formed on the other surface of said insulating layer and electrically connected to said contact terminals through via interconnect lines,
wherein said contact terminals have metal projections in the shape of quadrangular pyramid and a part of the quadrangular pyramid of said metal projection is composed of an insulator.

2. A connecting apparatus electrically contacting with an object to be inspected and inputting and outputting electrical signals, comprising:
contact terminals contacting with said object to be inspected;
a first insulating layer having said contact terminals provided on one surface thereof;
a first wiring layer formed on the other surface of said first insulating layer and electrically connected to said contact terminals through via interconnect lines;
a second insulating layer having said first wiring layer provided on one surface thereof; and
a second wiring layer formed on the other surface of said second insulating layer and electrically connected to said first wiring layer through via interconnect lines,
wherein said contact terminals have metal projections in the shape of quadrangular pyramid and a part of the quadrangular pyramid of said metal projection is composed of an insulator.

3. The connecting apparatus according to claim 1,
wherein said part of the quadrangular pyramid of said metal projection is a part of the bottom portion of said metal projection.

4. The connecting apparatus according to claim 1,
wherein each of said contact terminals has a plurality of tip portions for one wiring.

5. The connecting apparatus according to claim 1,
wherein said connecting apparatus has a holding member for fixing a peripheral portion of the insulating layer on which said contact terminals are provided, a pressing piece for projecting said contact terminals from said holding member, and a center pivot for pushing said pressing piece.

6. The connecting apparatus according to claim 5,
wherein said pressing piece has a protruding portion with a flat surface,
a buffer layer in contact with said protruding portion is provided, and
a region in which said contact terminals are arranged is projected along the flat surface of said protruding portion with sandwiching said buffer layer therebetween.

7. The connecting apparatus according to claim 6,
wherein said pressing piece has screws which are screwed up at the left, right, back and forth around said center pivot to be adjustable, and
a projecting amount of the region in which said contact terminals are arranged is defined in accordance with a protrusion of said screws from a surface of the protruding portion of said pressing piece.

8. The connecting apparatus according to claim 1,
wherein said contact terminal is made of at least one metal or alloy of metals selected from a group including nickel, rhodium, palladium, iridium, ruthenium, tungsten, chromium, copper and tin.

9. A semiconductor chip inspecting apparatus which uses the connecting apparatus according to claim 1.

10. The semiconductor chip inspecting apparatus according to claim 9, comprising:
a sample support system for supporting a wafer to be inspected;
an inspection connecting system including said connecting apparatus which contacts with electrode pads of semiconductor chips on said wafer to transmit electrical signals;
a drive control system for controlling an operation of said sample support system;
a temperature control system for controlling a temperature of said wafer; and
a tester for inspecting electrical properties of said semiconductor chip.

11. A method of manufacturing a semiconductor device, comprising the steps of:
fabricating circuits on a wafer to form a plurality of semiconductor elements;
sealing said wafer with resin;
collectively inspecting electrical properties of the plurality of semiconductor elements formed on said sealed wafer; and
cutting said wafer to separate each of said semiconductor elements,
wherein said inspecting step uses the semiconductor inspecting apparatus according to claim 10.

12. The method of manufacturing a semiconductor device according to claim 11,
wherein said inspecting step includes a step of evaluating electrical properties at high temperature.

13. The connecting apparatus according to claim 2,
wherein said part of the quadrangular pyramid of said metal projection is a part of the bottom portion of said metal projection.

14. The connecting apparatus according to claim 2,
wherein each of said contact terminals has a plurality of tip portions for one wiring.

15. The connecting apparatus according to claim 2,
wherein said connecting apparatus has a holding member for fixing a peripheral portion of the insulating layer on which said contact terminals are provided, a pressing piece for projecting said contact terminals from said holding member, and a center pivot for pushing said pressing piece.

16. The connecting apparatus according to claim 15,
wherein said pressing piece has a protruding portion with a flat surface,
a buffer layer in contact with said protruding portion is provided, and
a region in which said contact terminals are arranged is projected along the flat surface of said protruding portion with sandwiching said buffer layer therebetween.

17. The connecting apparatus according to claim 16,
wherein said pressing piece has screws which are screwed up at the left, right, back and forth around said center pivot to be adjustable, and
a projecting amount of the region in which said contact terminals are arranged is defined in accordance with a protrusion of said screws from a surface of the protruding portion of said pressing piece.

18. The connecting apparatus according to claim 2,
wherein said contact terminal is made of at least one metal or alloy of metals selected from a group including nickel, rhodium, palladium, iridium, ruthenium, tungsten, chromium, copper and tin.

19. A semiconductor chip inspecting apparatus which uses the connecting apparatus according to claim 2.

20. The semiconductor chip inspecting apparatus according to claim 19, comprising:
a sample support system for supporting a wafer to be inspected;
an inspection connecting system including said connecting apparatus which contacts with electrode pads of semiconductor chips on said wafer to transmit electrical signals;
a drive control system for controlling an operation of said sample support system;
a temperature control system for controlling a temperature of said wafer; and
a tester for inspecting electrical properties of said semiconductor chip.
